(19) United States
(12) Patent Application Publication
(10) Pub. No.: US 2003/0089680 A1
(43) Pub. Date: May 15, 2003

(54) Method and apparatus for the etching of photomask substrates using pulsed plasma

(76) Inventors: David J. Johnson, Palm Harbor, FL (US); Shinzo Onishi, Palm Harbor, FL (US); Christopher Constantine, Safety Harbor, FL (US)

Correspondence Address: Harvey S. Kauget, Holland & Knight LLP, Suite 2300, 400 N. Ashley St., Tampa, FL, 33602, US

(21) Appl. No.: 10/278,035

(22) Filed: Oct. 22, 2002

Related U.S. Application Data
(60) Provisional application No. 60/342,695, filed on Oct. 22, 2001.

(51) Int. Cl. C23F 1/00; B44C 1/22; C03C 25/68; H01L 21/461; C23C 16/00

(52) U.S. Cl. 216/68; 118/723 I; 156/345.48; 438/714; 438/710

(57) ABSTRACT

Disclosed is a method and apparatus for the etching of a thin film upon a photomask. The etching is carried out in a reactor via an inductively coupled pulsed plasma. Pulsing of the plasma is achieved by regulating the time period (or duty cycle) in which the plasma is generated. It has been found that by decreasing the duty cycle, high etch selectively can be achieved and feature sizes can be faithfully maintained.

### CROSS REFERENCE TO RELATED APPLICATIONS

This application claims priority from and is related to commonly owned U.S. Provisional Patent Application Serial No. 60/342,695, filed Oct. 22, 2001, entitled: ETCHING OF PHOTOMASK SUBSTRATES USING PULSED PLASMA, this Provisional Patent Application is incorporated by reference herein.

### TECHNICAL FIELD

The present invention relates to semiconductor processing. More particularly, the invention relates to an apparatus and method for the pulsed plasma etching of photomasks.

### BACKGROUND

Dry etching of photomasks is becoming the standard for the current generation of semiconductor devices. This is because in this current generation, device geometries have moved inside the 0.12 μm level, where wet etching can not achieve the desired precision. Dry etching is also the standard for the etching of binary masks, where the pattern is defined in materials such as chromium (Cr) or chromium oxides (CrOₓ), and in phase-shift masks in which the pattern is defined in a partially absorbing phase shifting layer, such as Molybdenum Silicide (MoSi).

Dry etching is particularly useful for anisotropic etching of a substrate. Anisotropic etching is etching that occurs primarily in one direction, whereas isotropic etching is etching that occurs in all directions. Anisotropic etching is desirable because it can be used to produce features having precisely located sidewalls that extend substantially perpendicularly from the edges of a masking layer. This precision is important in devices that have a feature size and spacing comparable to the depth of the etch.

To accomplish an anisotropic plasma etch, a substrate such as a photomask may be placed in a plasma reactor such that the plasma sheath of the resulting plasma forms an electric field perpendicular to the substrate surface. This electric field accelerates ions perpendicularly toward the substrate surface for etching.

The dry etching process is advantageous as it allows for the reproduction of dimensions as written into the photoresist masking layer. The quality of the etch is typically determined by comparing critical dimensions (CDs) in the photoresist masking layer and in the Cr or MoSi layer (the etched layer) after etching. Ideally, the CD bias, the difference between the CD in the photoresist masking layer and the CD in the etched layer, should be close to zero, and for example, less than 20 nm. The uniformity of the CD bias should also be small, for example, with a 3σ variation of less than 10 nm.

One form of dry etching is inductively coupled plasma etching. Inductively coupled plasma (ICP) etching is typically employed to etch Cr or MoSi for photomask applications, and can be applied to other materials, which may be used for the fabrication of binary or phase shifting photomasks. Systems for inductively coupled plasma etching provide for stable operation at low pressures with reasonable etch rates and low inherent ion bombardment, unlike reactive ion etching (RIE) at low pressures.

These systems include an induction coil, surrounding, or in close proximity to, the reaction chamber, to inductively couple power to a gas in the chamber to form a plasma. Power is supplied by an RF generator and a matching network is employed to match the impedance of the power supply with that of the plasma. The RF energy coupled inductively primarily determines the plasma ion density. A separate RF power supply is used to bias the substrate, to independently control the energy of the ions bombarding the substrate. The low pressure of operation inside the chamber, typically less than 10 mTorr, ensures etch rate uniformity, and the RF bias ensures anisotropic etching of materials, such as Cr and MoSi.

However, contemporary etch systems are limited, in that they only provide a CD bias of 60-70 nm and a 3σ variation of about 12 nm. One reason for this large CD bias is due to the amount of resist lost during the etch. If the resist removal is anisotropic (etching primarily occurring in one direction), and if the resist edge profile is sloped, a loss in resist thickness results in a reduction in feature size. If the resist loss is isotropic (in all directions) this will result in a reduction of feature size even if the resist profile is not sloped. In either case, the change in feature size is due to the reduction in resist dimensions, which increases with the amount of resist lost. For current etch processes, the etch selectivity to photoresist is poor and is typically approximately 1:1. Accordingly, when etching a 1000 Angstrom thick Cr film, and including 50% over etch, as much as 1500 Angstroms of the photoresist layer can be lost during the etch process. With a resist slope of 75 degrees (i.e. 15 degrees from vertical) this can translate to a CD loss of as much as 80 nm.

### SUMMARY

It is therefore one of the objectives of this invention to improve on the contemporary art by providing a method and apparatus that allows binary or phase shifting materials, such as Cr or MoSi, to be etched with a high selectivity with respect to the photoresist layer. The methods disclosed provide for the etching of Cr and MoSi layers in an inductively coupled plasma reactor system where etching thereof is approximately twenty times faster than the etching of the photoresist layer (an etch selectivity of 20:1). As a result of this method, and the apparatus useful in performing these methods, etching of features can be performed with a minimum loss of the photoresist layer, whereby the CD bias and CD uniformity values are improved significantly with respect to those of the contemporary art.

It is an additional object of this invention to pulse the inductively coupled plasma off and on in cycles to thereby increase etch selectivity while at the same time maintaining an anisotropic etch.

It is an additional object of this invention to use a pulsed plasma to take advantage of the difference in the lifetime of species created within the plasma and facilitate chemical etching primarily by neutral radicals.

It is a further object of this invention to use a pulsed plasma to regulate the density of neutral radicals and ions.

It is still yet another object of this invention to facilitate anisotropic etching by applying a bias voltage to the substrate being etched.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The invention will become more readily apparent from the following description, by way of example only, in the accompanying drawings wherein corresponding or like numerals and characters indicate corresponding or like components. In the drawings:

FIG. 1 is an illustration of an exemplary processing chamber used with embodiments of the present invention;

FIGS. 2 and 2a are illustrations of a photomask;

FIG. 3 is a diagram of plasma optical emissions when the induction coil is pulsed for 800 μs;

FIG. 4 is a diagram of etching rate versus duty cycle;

FIG. 5 is a diagram of etching rate versus pressure; and

FIG. 6 is a box plot of actual critical dimensions (CD) and their deviations from the average CDs in accordance with an embodiment of the present invention.

### DETAILED DESCRIPTION OF THE INVENTION

The present invention relates to the etching of a thin film upon a photomask. The etching is carried out in a reactor via an inductively coupled pulsed plasma. Pulsing of the plasma is achieved by regulating the time period (or duty cycle) in which the plasma is generated. It has been found that by decreasing the duty cycle, high etch selectively can be achieved and feature sizes can be faithfully maintained. The apparatus and method for carrying out the present invention are described in greater detail hereinafter.

Reactor Configuration

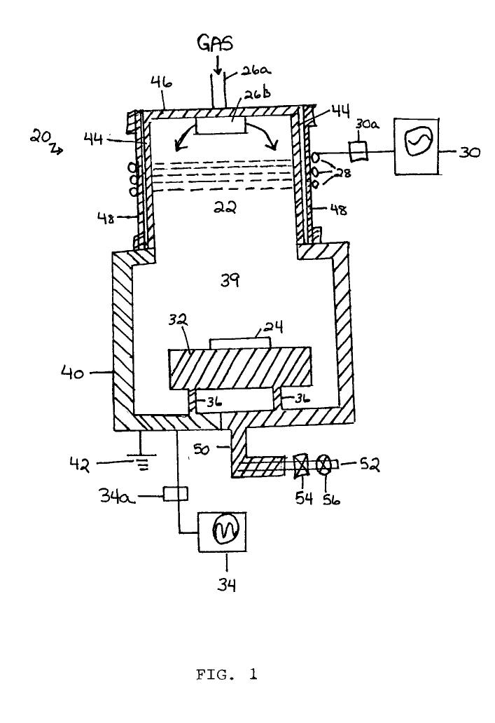

FIG. 1 illustrates a cross-sectional view of an inductively coupled plasma (ICP) reactor system 20 for use with the present invention. The system includes a plasma generation chamber 22, where semiconductor substrates 24 or workpieces, such as photomasks, are etched. Gas is supplied to the chamber 22 through supply lines 26a and 26b connected to a conventional gas source (not shown).

The system 20 is configured such that the energy of ions bombarding the substrate 24 can be controlled substantially independently of the ion density. Induction coils 28, connected to a first RF power source 30, encircle (and are adjacent to) the plasma generation chamber 22. A separate electrode 32 is connected to a second RF power source 34 and acts as a support for the substrate 24. The power applied to the electrode 32 is used to control ion bombardment energies, by providing a bias voltage, while the power applied to induction coils 28 is used to control the plasma ion density. Both power supplies are equipped with an automatic matching network (AMN), 30a and 34a, in a manner known in the art. The ICP reactor of FIG. 1 is only representative and the use of other reactor configurations is within the scope of the present invention. For example, the present invention can be carried out in a flat reactor geometry. Other induction coil geometries are also within the scope of the present invention, such as the use of helical coil arrangements.

The electrode 32 is made of a conductive material. It is typically supported by a support 36 of an insulating or non-conductive material, such as a ceramic. The electrode is located in a processing chamber 39, which is connected to the plasma generation chamber 22.

The wall 40 of the processing chamber 39 is grounded. This wall 40 provides a common ground 42 for the system 20 and includes a conductive material. The wall 40 attaches to walls 44 of the plasma generation chamber 22. These walls 44 are made of nonconductive material, such as quartz or alumina. Lid 46 connects to the walls 44 and covers the plasma generation chamber 22. In one exemplary embodiment, a split Faraday shield 48 extends around the walls 44. The shield 48 reduces capacitive coupling between the coil and the plasma. Nonetheless, it is within the scope of the present invention to use a reactor without a Faraday shield. The entire system may be enclosed by a shield (not shown) of a radiation shielding material such as aluminum or the like.

A gas exhaust system 50 is below the support 32. This exhaust system 50 typically includes an outlet conduit 52, a shut-off valve 54 and a control valve 56 for permitting pressure control.

The gas mixture, from which the plasma is formed, consists of a Cl-containing gas, such as HCl, Cl₂ or the like, and an O-containing gas, such as O₂, CO₂ or the like, and may additionally contain an inert gas such as He, N₂ or the like. In the case of a photomask with a chromium layer, plasma etching is preferentially carried out using a mixture of O₂ and Cl₂ gas. The preferred gas mixture is approximately 90% Cl₂+10% O₂. The gas mixture is pressurized at approximately 10-20 millitorrs (mTorr) and enters the plasma chamber 22 at a flow rate of approximately 100-200 standard cubic centimeters per minute.

The induction coils 28 couple energy into the gas in the plasma generation chamber 22 during high power cycles to produce a plasma. During high power cycles, the induction coils 28 produce a circumferential electric field in the plasma generation chamber 22 that is substantially parallel to the surface of the substrate (workpiece) 24. Typically, the power supplied during the high power cycles has a magnitude of less than about 5 kilowatts. The electric field accelerates electrons in the gas and a plasma results. Within the plasma a wide variety of reactive species are created, including electrons, neutral radicals, positive ions and negative ions. Once created, these reactive species are free to etch the photomask (both chemically and through ion bombardment) in a manner more fully described hereinafter.

Photomask Construction

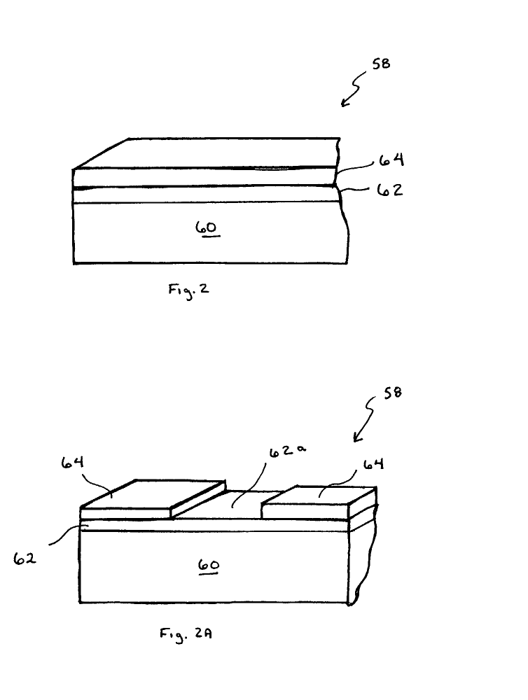

In a first embodiment, the workpiece to be etched within the reactor takes the form of a photomask or reticle 58. FIG. 2 illustrates one typical photomask construction. The photomask 58 includes a first substrate 60, which is formed from a suitable material that is transparent to the electromagnetic radiation typically employed in semiconductor lithographic operations. Suitable materials include silica glass, fused quartz, and borosilicate glass. In the preferred embodiment, substrate 60 is formed from quartz.

A thin layer 62 is then deposited over substrate 60. In the case of a binary photomask, layer 62 is formed from a light blocking material. For example, layer 62 can be formed from a metal such as chromium (Cr). However, if the photomask is a phase shifting mask, layer 62 will be partially light transmissive and formed from a light attenuating material such as MolySilicide (MoSi). The use of additional materials for layer 62 is also within the scope of the present invention.

Finally, a photoresist layer 64 is placed over layer 62. In a manner known in the art, the resist layer 64 is then exposed to write equipment to write a circuit design onto the mask. The write equipment can take the form of an e-beam or other high precision photolithographic means. Thereafter, developing processes are employed to remove the exposed resist. The resulting product is illustrated in FIG. 2a. As illustrated, the upper surface of the resulting mask includes both unexposed resist 64 and the underlying layer 62a both of which are subsequently etched via a plasma.

Plasma Pulsing

As explained, the gas supplied to chamber 22 is ignited into a plasma when power is supplied to induction coils 28. In an important aspect of the present invention, the induction coils are pulsed “on” and “off” for various time periods. The resulting pulsing of the plasma dramatically increases etch selectively and improves the quality of the resulting etch.

The increase in etch selectively is a function of the Cr etch rate being independent of the bias voltage on the electrode 32. This indicates that the etch rate of the Cr is not based upon ion bombardment. Rather, the Cr etch rate is chemically driven, specifically, by the reaction of the Cr with the Cl and O radicals generated by the disassociation of the Cl₂ and O₂ in the plasma. This chemical reaction forms CrO₂Cl₂ as a volatile etch product as the Cr is etched. Similar etch characteristics are expected using other Cl-containing precursors (e.g. HCl, CCl₄, etc.) and O-containing precursors (e.g. CO, CO₂ etc.). This chemical etching continues even after power to the induction coils 28 has been turned “off” (to zero) due to the slow decay of the uncharged radicals (for example, Cl and O) in the gas mixture. The decay of these uncharged radicals is typically on the order of milliseconds to seconds, depending on the geometry of the chamber.

The chemical etching of the Cr is in contrast to the etching of the photoresist layer. Here, the etch rate is highly dependent on the bias voltage which indicates that the photoresist is primarily etched by ion bombardment. In this regard, etching of the resist is dependent upon the presence of ions generated in the plasma. Thus, it has been found that the highest selectivity for etching occurs when the bias voltage is low or even zero, i.e., in the absence of ion bombardment. However, even when the bias voltage is zero, a limited amount of ion bombardment continues due to the potential created by the plasma (20-30 volts).

The above pulsing process can also be carried out on a workpiece 24 formed of MoSi with a photoresist layer over it. When working with the MoSi workpiece, fluorine (F) is used in the gas mixture for the plasma, for example, CF₄ or SF₆ or the like. Here, the neutral F radicals chemically interact with the MoSi layer to create a volatile etch product.

In addition, any etchable layer that is incorporated on a photomask, such as, but not limited to, Nb-, Ti-, Ta-, and Si-containing materials can be etched with a greater selectivity over the prior through the use of the present invention. In such cases the etching is by reaction with radicals and the etch rate of the etchable layer is primarily chemically driven. By regulating the time periods in which the plasma is pulsed on and off (i.e. the duty cycle) one can take advantage of the major difference in the lifetime of the species of radicals formed in the plasma. Specifically, after RF power is removed from the induction coils 28, plasma generation ceases and the density of charged particles falls very quickly to close to zero (few tens of microseconds). However, the density of un-charged radicals (e.g., Cl, O, F) decays much more slowly, and may be of the order of milliseconds to seconds, depending on the reactor geometry. Since these neutral species are primarily responsible for chemically etching Cr, MoSi or the etchable layer, the etching continues even after the plasma is extinguished. During this period (the time period after the plasma is pulsed off, but before the decay of the un-charged radicals), the lack of charged particles means that there is no ion bombardment and hence the resist etch rate is very low. Therefore, during this time period, the selectivity of etching Cr:photoresist, MoSi:photoresist or the etchable layer:photoresist is dramatically increased.

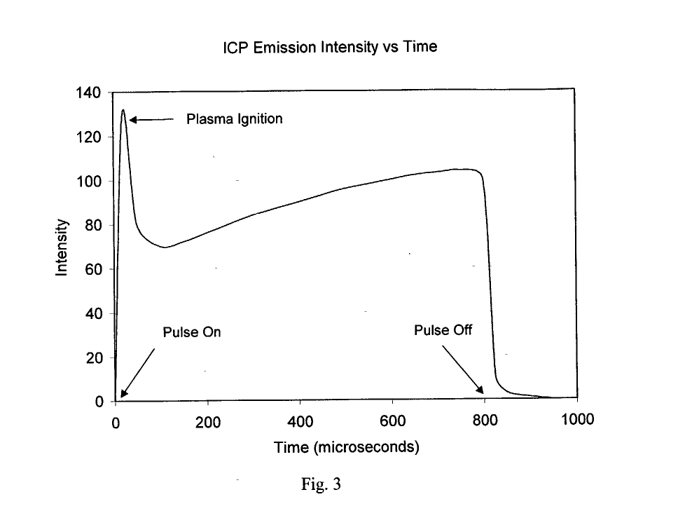

After the plasma is pulsed off, the un-charged radical concentration eventually decays to zero and the etch rate of Cr, MoSi or the etchable layer falls to zero. Thus, the plasma needs to be pulsed back on to create additional radicals. The generation of a steady-state plasma takes place quickly after the RF power is applied to induction coils 28, in a time frame of the order of a hundred to a few hundred microseconds. FIG. 3 shows the plasma optical emission during this phase and shows the formation of a steady state plasma in approximately 500 μS. Even after 100 μS the emission from the plasma has reached >75% of the steady state value. During this time the concentration of radicals (Cl, O, F) also reaches a steady state. The duration of the off cycle is primarily a function of the decay rate of the uncharged radicals, and ideally would be long. However, it has been found that reigniting the plasma becomes more difficult as the off cycle is increased. Thus, the duration of the off cycle is also a function of the ability of the induction coil to reignite the plasma.

By pulsing the plasma on and off with an “on” time of the order of 100 microseconds (determined primarily by the formation of steady-state conditions) and an “off” time of the order of a few milliseconds (determined by the radical decay time) it is possible to greatly enhance the Cr:photoresist etch selectivity. The Cr is etched during the whole cycle, i.e., during the “on” and “off” period of the plasma, while the resist is etched only during the “on” period. Using the described pulsing method, it has been found that etching with an inductively coupled plasma results in the Cr (or MoSi) being etched up to 20 times faster than the photoresist layer, or at an etch selectivity of 20:1. This allows workpieces to be etched with a minimal loss of photoresist. As a result, CD bias and CD uniformity are significantly improved when compared to conventional etching techniques.

Substrate Bias Voltage

Bias voltage to electrode 32 is typically low or zero. The bias voltage can be applied as either a continuous bias or a pulsed bias. If pulsed, the pulse can be in phase (when the induction coils are “on”), or out of phase (when the induction coils are “off”). The pulsed bias can also be adjusted independently of the pulse or power applied to the induction coils. For example, the bias voltage can be applied at frequencies of approximately 50 kHz to approximately 1 MHz, or at higher frequencies, such as 13.56 MHz. In various embodiments, the bias voltage of the substrate may be alternated between high and low cycles, “on” and “off” cycles, or may be completely “on” at a predefined voltage or “off”.

It has been found that applying a bias voltage increases ion bombardment and decreases selectivity, with the highest selectivity occurring when no bias voltage is applied. Nonetheless, the bias voltage promotes anisotropic etching. Thus, some bias voltage is desirable to achieve a proper etch profile.

The present invention is also defined by the following Examples:

### EXAMPLE 1

In this Example, a Cr workpiece, for example, a binary mask (photomask) with a layer of photoresist over it was subjected to a plasma pulsed on and off with an “on” time of 100 μs and an “off” time that was varied from zero to 2 milliseconds so as to define Duty Cycles from greater than zero to less than 100%. No bias voltage was applied. Process conditions were as follows:

| | |
|---|---|
| Cl₂ | 48 sccm |
| O₂ | 14 sccm |
| He | 22 sccm |
| Pressure | 3.7 mTorr |
| ICP Power | 1800 Watts |

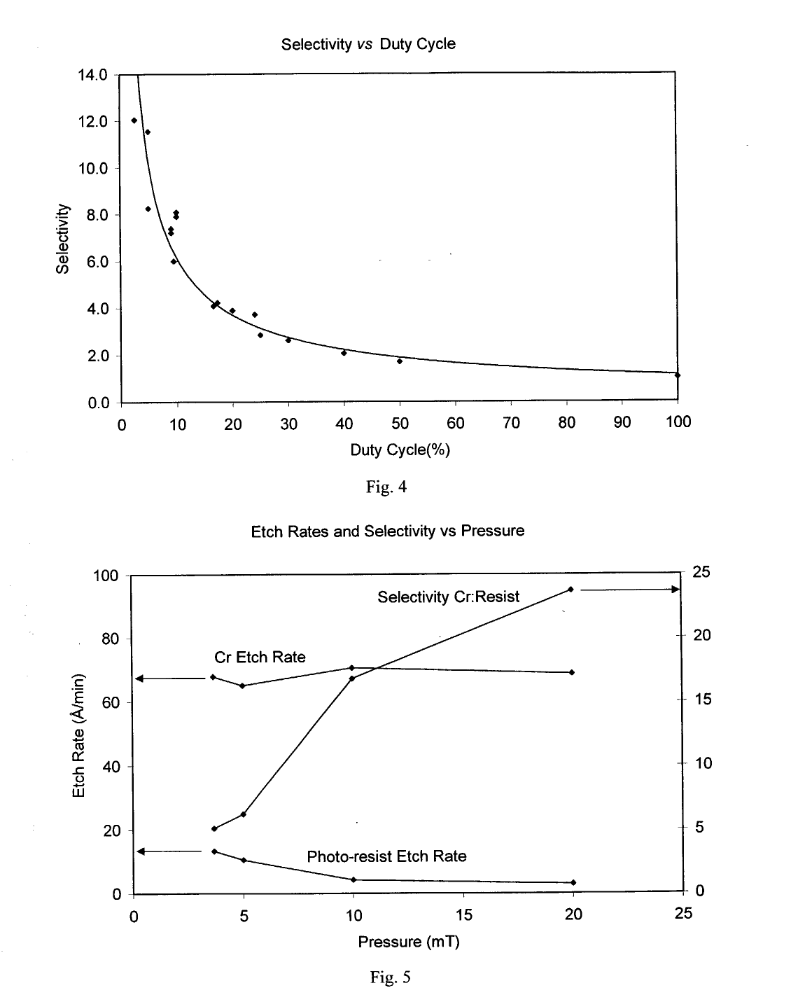

Results are shown in FIG. 4. Here, the highest selectivity occurred when the plasma was pulsed “on” at 100 μs and the pulse was “off” for 2 milliseconds, such that the duty cycle was approximately 5%. It was found that the Cr was etched during the entire cycle while the photoresist layer was etched only during the “on” or pulsed portion of the cycle.

### EXAMPLE 2

The process of Example 6 was repeated, except that the plasma was operated at higher pressures, up to 20 mTorr. Results of etching rates and selectivity of Cr:photoresist versus the pressure are shown in FIG. 5. Specifically, this increase in pressure resulted in the etch rate of the photoresist being reduced, further than in Example 6, and the Cr:photoresist selectivity was greater than 20:1. A similar response happens while etching MoSi with F radicals. Likewise, a similar response occurs while etching other materials (the etchable layer) where the etching of one material is primarily chemically driven (the etchable layer) and the other material (photoresist) is primarily etched by ion bombardment.

### EXAMPLE 3

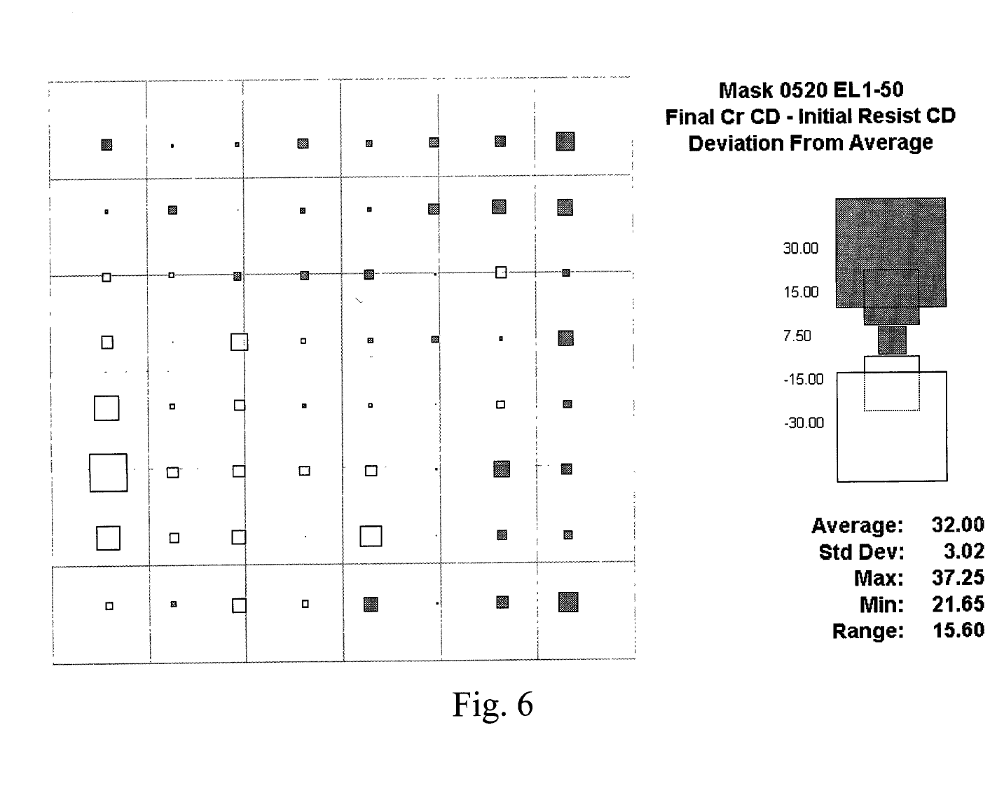

A Cr photomask was etched to its etch end point followed by a 100% over etch in accordance with the process of Example 2 above. The critical dimensions (CDs) in the photoresist layer (before etching) were compared with the critical dimensions (CDs) in the Cr after etching. The results are shown in the Box Plot of FIG. 6. In the box plot of FIG. 6, the average CD Bias is approximately 32 nanometers (nm), while the CD variation is approximately 9 nm (3 sigma).

In Examples 1-3, it was found the highest selectivity was obtained when an RF bias of zero is applied to the substrate (workpiece). However, some RF bias can be applied to improve the etch sidewall profile. In applying this bias, a balance is achieved between sidewall improvement and selectivity reduction. This bias can be applied continuously or can be pulsed either in or out of phase with the ICP pulse.

While the above Examples have been performed on a Cr workpiece for a binary mask (photomask), these examples can also be performed with a MoSi workpiece for a phase-shift photomask with F radicals in the etchant plasma.

While preferred embodiments of processes, methods, systems, apparatus, and components, have been described above, the description above is exemplary only. Those skilled in the art will recognize, or be able to ascertain using no more than routine experimentation, many equivalents to the specific embodiments of the invention described herein. Such equivalents are intended to be encompassed by the following claims.

What is claimed is:

1. An apparatus for processing a photomask comprising:
a processing chamber;
an etchant gas;
an induction coil adjacent to at least a portion of the processing chamber, the induction coil configured for receiving power applied thereto to inductively couple power into the processing chamber and produce at least one plasma;
a first pulsed power source coupled to the induction coil such that power to the induction coil is turned on and off in alternating cycles;
a substrate support positioned adjacent to the at least one plasma for supporting a substrate; and
a second power source coupled to the substrate support for applying a bias to the substrate.

2. The apparatus of claim 1, wherein the second power source is a pulsed power source.

3. The apparatus of claim 1, wherein power to the induction coil is pulsed off for a period of time less than 5 milliseconds.

4. The apparatus of claim 1 wherein the ratio of the on time of the induction coil to the off time of the induction coil is less than 25%.

5. The apparatus of claim 1 wherein the ratio of the on time of the induction coil to the off time of the induction coil is between 5-10%.

6. The apparatus of claim 1 wherein the photomask is a phase shifting mask.

7. The apparatus of claim 1 wherein the photomask is a binary photomask.

8. The apparatus of claim 1 wherein the photomask contains a layer formed from either Chromium (Cr) or MolySilicide (MoSi).

9. The apparatus of claim 1 wherein the photomask contains an etchable layer where the etching of said etchable layer is by reaction with radicals and the etch rate of said etchable layer is primarily chemically driven.

10. The apparatus of claim 1 wherein the etchant gas is supplied at a pressure of between 10 to 20 mTorr.

11. The apparatus of claim 1 wherein etchant gas etches the substrate to produce CrO₂Cl₂.

12. A method for processing a substrate comprising:
providing a reactor chamber for producing a plasma;
supplying an etchant gas into said reactor chamber;
pulsing in an on and off manner a first pulsed power source for inductively coupling power to at least a portion of the reactor chamber to thereby create a plasma with radicals, electrons and ions, wherein etching of the substrate occurs primarily by the chemical interaction between the radicals and the substrate;
positioning the substrate on a substrate support adjacent to the plasma.

13. The method of claim 12 including the additional step of biasing the substrate during processing through a second power source coupled to the substrate support.

14. The method of claim 13 wherein the second power source is a pulsed power source.

15. The method of claim 11 wherein the induction coil further comprising a Faraday shield.

16. The method of claim 12 wherein the first pulsed power source is turned off for a time period of less than 5 milliseconds.

17. The method of claim 12 wherein the ratio of the on time of the first pulsed power source to the off time of the first pulsed power source is less than 25%.

18. The method of claim 12 wherein the ratio of the on time of the first pulsed power source to the off time of the first pulsed power source is between 5-10%.

19. The method of claim 12 wherein the substrate is a photomask.

20. The method of claim 19 wherein the photomask includes a layer of chromium.

21. The method of claim 19 wherein the photomask is a binary photomask.

22. The method of claim 19 wherein the photomask is a phase shifting photomask.

23. The method of claim 19 wherein the photomask contains an etchable layer where the etching of said etchable layer is by reaction with radicals and the etch rate of said etchable layer is primarily chemically driven.

24. The method of claim 12 wherein the etchant gas is supplied at a pressure of between 10 to 20 mTorr.

25. A method of employing a plasma reactor to etch a thin film upon a substrate, the method comprising the following steps:
supplying a gas to the plasma reactor;
inductively coupling power to the reactor to produce a plasma, production of the plasma causing the creation of electrons, positive ions, negative ions and neutral radicals, the neutral radicals being chemically reactive with the thin film on the substrate;
ceasing the inductively coupled power such that the plasma decays, wherein after substantial decay of the plasma, the neutral radicals continue to chemically etch the thin film on the substrate.

26. The method of claim 25 wherein the inductively coupled power is repeatedly pulsed off and on.

27. The method of claim 26 wherein the ratio of the on time to the off time is less than 25%.

28. The method of claim 26 wherein the ratio of the on time to the off time is between 5-10%.
